(19) United States
(12) Patent Application Publication
(10) Pub. No.: US 2022/0357238 A1
(43) Pub. Date: Nov. 10, 2022

(54) ENERGY HARVESTING SENSORS AND METHODS

(71) Applicant: Dodge Acquisition Co., Oxford, CT (US)

(72) Inventors: Marius Rutkevicius, Raleigh, NC (US); Graham Medlin, Durham, NC (US); Stefan Rakuff, Garner, NC (US); Rajib Mikail, Raleigh, NC (US); Matthew Hetrich, Raleigh, NC (US); Vasilios B. Kapousidis, Greenville, SC (US); Isaac P. O'Brien-Herr, Greer, SC (US); Wei Xing, Raleigh, NC (US)

(73) Assignee: Dodge Acquisition Co., Oxford, CT (US)

(21) Appl. No.: 17/313,384

(22) Filed: May 6, 2021

(51) Int. Cl. G01M 13/04; H02J 7/34; H05K 7/20; H02J 7/35; F16C 35/04

(52) U.S. Cl. CPC G01M 13/04; H02J 7/345; H05K 7/20163; H02J 7/35; F16C 35/042; H02J 2207/20

(57) ABSTRACT

A sensor system for monitoring a device, the sensor system including a housing, a base configured to attach the sensor system to the device to be monitored, a sensor configured to obtain data related to at least one operating parameter of the device, and an integral energy harvesting device configured to provide at least a portion of the energy required to operate the sensor system.

### FIELD OF THE DISCLOSURE

The present disclosure relates to diagnostic sensors and energy harvesting.

### BACKGROUND

Sensors for acquiring data related to operating parameters of mechanical equipment may use battery power or external power provided via wiring to operate the sensor. Battery power provides a limited operating lifespan due to the limited capacity of current battery technology, and external power increases installation complexity and requires a readily available power source. In order to increase the lifespan of battery-powered sensors, such devices are typically triggered and/or operated at a reduced frequency to increase the lifetime of the battery, thus sometimes failing to detect important equipment operating parameters and reducing the functional potential of the sensor. Increasing the sampling rate and functionality of such a sensor would require more frequent replacement of the battery, and in cases where the battery is non-replaceable it would be necessary to replace the entire sensor.

For sensors connected to a remote power source by electrical wires, which allows for battery-less operation, wires can be a hazard in many locations, are easily damaged, and have the disadvantage of increasing installation time and complexity. Further, connection to a remote power supply by wires may not be an option on some purely mechanical devices. Thus, there is a need for an improved means of powering sensors.

### BRIEF SUMMARY OF THE DISCLOSURE

The invention describes sensors and methods of operating such sensors. In one aspect, the present disclosure enables the extension of battery lifetime of battery-operated sensors or the operation of battery-less sensors, by harvesting energy available in the local environment. This energy may be, for example, in the form of heat, light, radiofrequency, mechanical vibration, and others. The energy is harvested through one or more devices, for example, a thermoelectric device, a photoelectric device, an antenna, a mechanical oscillator, and the like.

In another aspect, the present disclosure describes a sensor system for monitoring a device, the sensor system including a housing, a base configured to attach the sensor system to the device to be monitored, a sensor configured to obtain data related to at least one operating parameter of the device, and an integral energy harvesting device configured to provide at least a portion of the energy required to operate the sensor system.

In yet another aspect, the disclosure describes a method for operating a wireless sensor system, including generating power with an integral energy harvesting device. The sensor system is booted to a state of full operation when the level of energy exceeds a selected threshold. The sensor system monitors the level of energy available for operation. The full state of operation is maintained while the level of energy exceeds that required for full operation of the system and the state of operation is reduces when the level of energy drops below the required level.

### BRIEF DESCRIPTION OF THE SEVERAL VIEWS OF THE DRAWINGS

FIG. 1 is a perspective view of a sensor and energy harvesting system according to the disclosure.

FIG. 2 is a section view of the sensor and energy harvesting system of FIG. 1.

FIG. 3 is a block diagram of the sensor and energy harvesting system according to FIG. 2.

FIG. 4 is a block diagram of an alternative sensor and energy harvesting system according to the disclosure.

FIG. 5 is a diagrammatic view of an alternative energy harvesting system for a sensor according to the disclosure.

FIG. 6 is a diagrammatic view of another alternative energy harvesting system for a sensor according to the disclosure.

FIG. 7 is a diagrammatic view of yet another alternative energy harvesting system for a sensor according to the disclosure.

FIG. 8 is an end view of a bearing assembly with a sensor system according to the disclosure attached to the housing of the bearing assembly.

FIG. 9 is a perspective view of a gearbox or motor with a sensor system according to the disclosure attached to the housing thereof.

FIG. 10 is a flowchart illustrating a method of operating the sensor system with an energy harvesting device in accordance with the disclosure.

### DETAILED DESCRIPTION

Throughout the drawings, identical reference numbers designate similar, but not necessarily identical, elements. The figures are not necessarily to scale, and the size of some parts may be exaggerated to more clearly illustrate the example shown. Moreover, the drawings provide examples and/or implementations consistent with the description; however, the description is not limited to the examples and/or implementations provided in the drawings. For purposes of description herein, the terms “upper”, “lower”, “left”, “rear”, “right”, “front”, “vertical”, “horizontal”, and derivatives thereof shall relate to the invention as oriented in the figures. Throughout the drawings, identical reference numbers designate similar, but not necessarily identical, elements. The figures are not necessarily to scale, and the size of some parts may be exaggerated to more clearly illustrate the example shown. Moreover, the drawings provide examples and/or implementations consistent with the description; however, the description is not limited to the examples and/or implementations provided in the drawings.

Where possible, any terms expressed in the singular form herein are meant to also include the plural form and vice versa, unless explicitly stated otherwise. Also, as used herein, the term “a” and/or “an” shall mean “one or more” even though the phrase “one or more” is also used herein. Furthermore, when it is said herein that something is “based on” something else, it may be based on one or more other things as well. In other words, unless expressly indicated otherwise, as used herein “based on” means “based at least in part on” or “based at least partially on”.

The term “sensor” is commonly used to indicate a device, module, machine, or subsystem that generates a signal responsive to a detected change in an environmental property and in some cases can also refer to a device with functionality in addition to detection. In the present case, the disclosure is directed to a sensor system with sensing, power generating, and wireless communication capabilities. Where the term indicates only the element that performs only the “sensing” function, such a device will be referred to herein as a sensor. When this disclosure is discussing more than only detection the disclosure will refer to a sensor system.

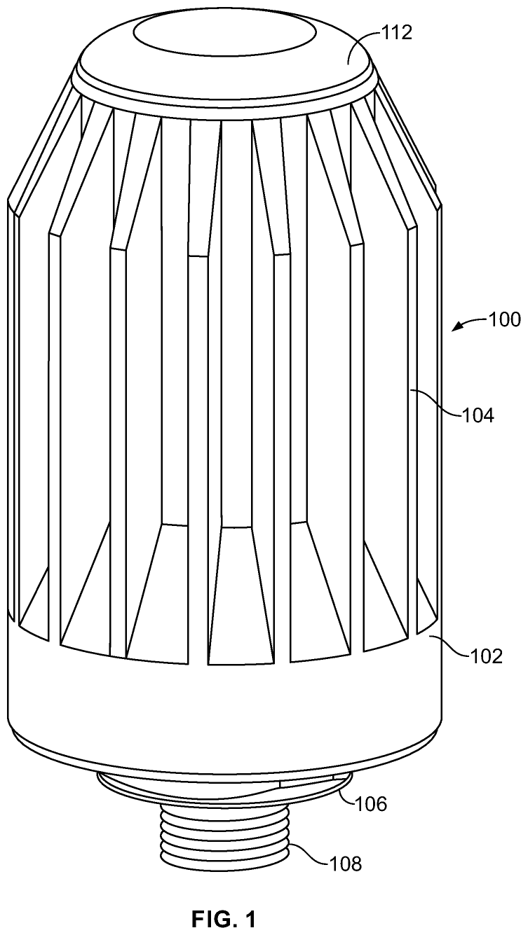

FIG. 1 shows a sensor system 100 according to the disclosure. The sensor system 100 includes a housing 102, a base portion 106, and an antenna 112. The sensor system 100 is embodied as a self-contained module or device, meaning all of the necessary elements for the sensor system to function independently to detect and transmit information is part of the system.

The housing 102 is configured to enclose and protect internal elements of the sensor system 100 as will be described hereinbelow. The housing 102 may be configured to function as a heat sink and therefore may include cooling fins 104 that dissipate heat. When configured to act as a heat sink, the housing 102 may be made of a material with a favorable thermal conductivity such as aluminum. The materials used in the system 100 and housing 102 may be dictated by safety regulations or concerns. For example, it is prohibitive to use aluminum in an explosive environment, and thus a steel material may be used, which has lower thermal conductivity relative to aluminum. Alternatively, the housing 102 may be configured without cooling fins when it is not necessary to dissipate heat. The housing 102 may be sealed or otherwise configured to protect the inner components from damage or contamination.

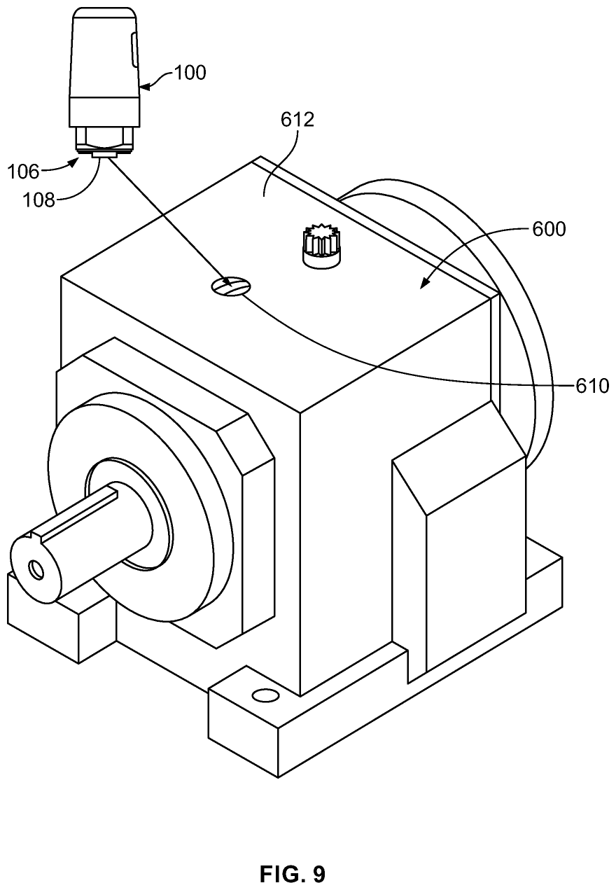

The base portion 106 includes a fastening element, which, in the present embodiment, includes a threaded post 108. The post 108 permits attachment of the sensor system 100 to a device to be monitored such as a bearing assembly, gearbox, or motor (FIGS. 8 and 9).

The antenna 112 is configured to enable wireless communication from the sensor system to remote devices, such as components of a wireless network including, for example, wireless repeaters and/or network gateway devices (not shown). The sensor system 100 is configured to send data packets from the sensor system and potentially receive signals from a remote source. It may be advantageous to position the antenna on the exterior of the housing 102 and generally opposite the post 108.

The sensor system 100 is configured to track and transmit parameters such as, for example, one or more of temperature, vibration, sound, speed, and oil properties, and may optionally perform data processing in the device (referred to as “edge computing”). The sensor system 100 is configured to transmit the data wirelessly to a server or a local data acquisition device, as is known, via the antenna 112. Such sensors provide valuable information about the current/historic operating conditions of the attached device and potentially information about the operating conditions of devices that are operationally associated with the attached device.

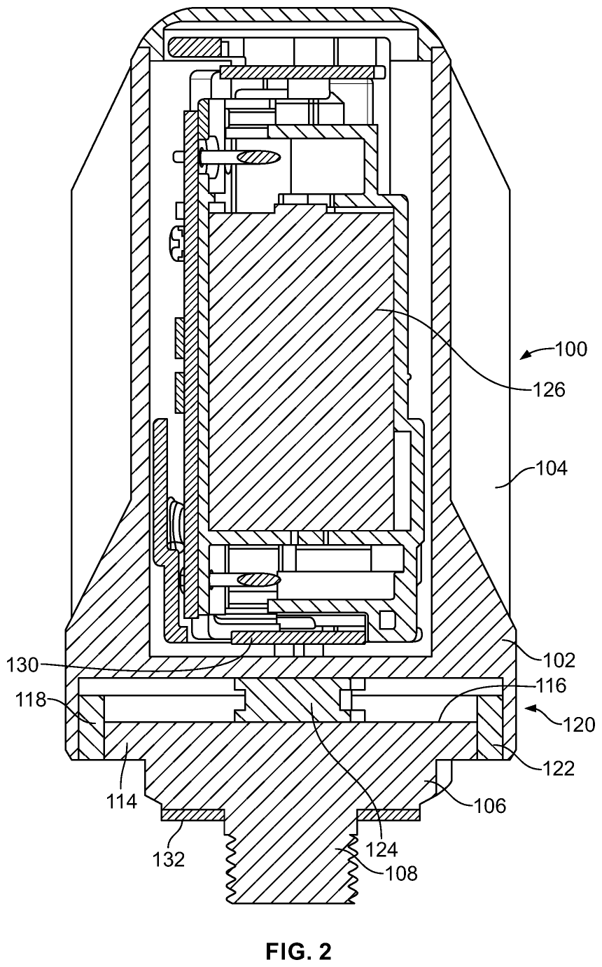

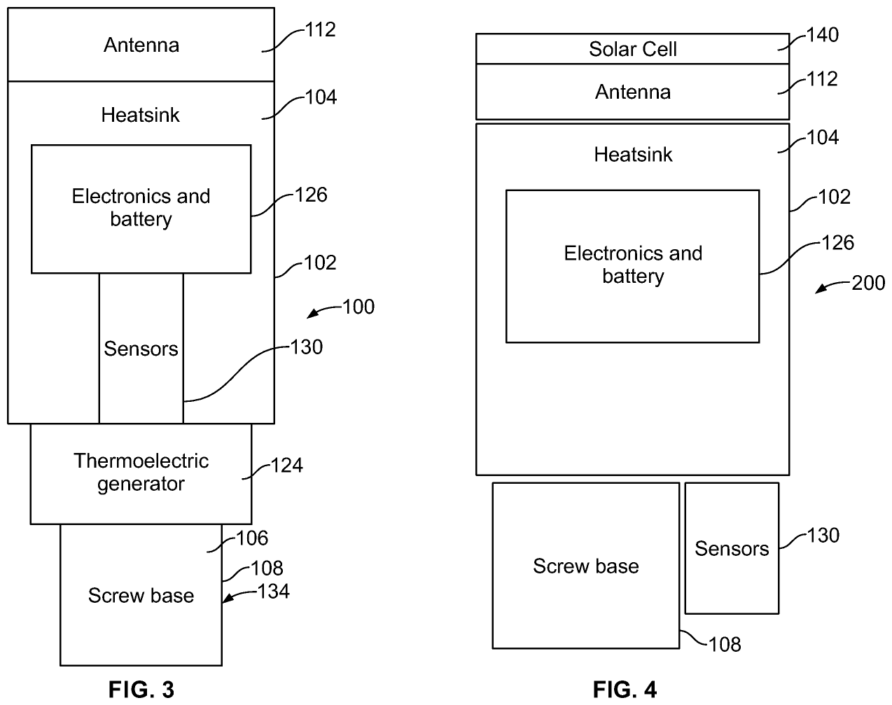

FIGS. 2 and 3 show a sensor system 100 according to an embodiment of the disclosure. The sensor system 100 includes a housing 102 with fins 104 for dissipating heat. The fins 104 may be made of a material with a high thermal conductivity, such as steel, aluminum, or copper, to function as a heat sink.

A base 106 is disposed at a lower end of the housing 102 and may have a generally round or disc-shaped portion 114 for connecting to the housing and an upper surface 116, which may be generally planar. The base 106 is made of a thermally conductive material, preferably metal-based, such as steel, aluminum, copper, or alloys of metals. In this and other, similar embodiments described herein, the base 106 may be connected to a structure disposed at a higher-than ambient temperature during operation. In this way, heat may transfer from the substrate onto which the base 106 is connected, to the base 106, and from the base through internal components and structures of the sensor system 100 conductively until it reaches the outer housing 102 and dissipate convectively therefrom to the environment. This path of heat transfer may create temperature gradients that begin from a first, highest temperature T1 at the substrate, and terminate at a lowest temperature T2 at the fins 104. Intermediate temperatures, Tn may exist at various locations internally or externally and along components of the sensor system 100.

In the illustrated embodiment, a threaded post 108 extends outwardly from the circular portion 114 opposite the upper surface 116. The housing 102 includes a blind hole 118, cavity, or receptacle formed on a bottom end 120 thereof sized and shaped to receive the circular portion 114 of the base 106. A thermal insulator 122, in this embodiment, is disposed between the base 106 and the interior wall of the blind hole 118. The thermal insulator 122 should be made of a thermally insulative material, such as a polymer, which can be thermoset or thermoplastic for example. Other embodiments that are configured to harvest non-thermal types of energy may not require the thermal insulator. In this embodiment, the thermal insulator 122 insulates the housing 102 and surrounding structures from receiving heat directly from the substrate surface onto which the sensor system 100 is installed, because such transfer would decrease the thermal gradient (T2−T1) available for energy harvesting, and ensures that heat transfers to the threaded post 108 and not to other portions of the sensor system 100.

An energy harvesting device 124, in this embodiment in the form of a heat flux generator, is positioned upon and in contact with the upper surface 116 of the base 106 in the blind hole 118 and in contact with the housing 102 such that heat can be conducted from the base to the heat flux generator and from the heat flux generator to the housing. The energy harvesting device 124 is integral to the sensor system 100, which will be understood to mean that the device is attached to and part of the sensor system.

The housing and heatsink 102, 104 are generally cylindrical, and at a lower portion 120 forms the blind hole 118. Shapes other than cylindrical can also be used. The blind hole 118 and the mounting base 106 enclose the energy harvesting device 124, as shown in FIG. 2, and protects components within the housing 102 as well as the energy harvesting device 124 from solid and liquid contaminants, such as dust, grease, and water. As will be discussed further herein with respect to alternative embodiments, the heat flux generator 124 may be replaced by any one of a variety of mechanisms to harvest energy from the environment.

Contact between the base and the energy harvesting device 124 may be of a direct metal-metal type, but suitable thermal conductive material layers may be used that are able to bridge any gaps from imperfections in the two mating surfaces to create a thermal contact interface without voids. Such thermally conductive interface layers may be comprised of soft malleable metals such as indium or lead or they can be comprised of thermal paste/grease or thermal adhesive/epoxy. Similarly, the interface between the cold (upper) side of the energy harvesting device 124 and heat sink 104 can be a direct contact or enhanced with a thermally conductive compound.

The energy harvesting device 124 may be based on a Peltier plate or, for example, a thermoelectric generator. A Peltier plate contains an array of semiconductor junctions. These junctions are connected in series and have a ceramic plate attached to either side, which when heated on one side and cooled on the other side generates an electric potential and current flow through the junctions. This current can be collected through the ends of the Peltier plate and used to power electric circuitry 126 of the sensor system 100. A Peltier plate is also called a thermoelectric cooler (TEC). A similar device is a thermoelectric generator (TEG), which has different materials used for soldering, with a flatter ceramic surface. However, a TEC can provide sufficient power for the smart sensor power demand as currently embodied.

The sensor system 100 may include a battery and suitable electronic circuitry 126 to perform the sensing functions of the system and optionally at least one of analytics and wireless communication functions. In particular, the circuitry 126 includes elements such as a process and sufficient memory to support the acquisition and processing of data from the sensor 130, and a wireless transceiver configured to wirelessly transmit data as is known in existing wirelessly sensors. In other embodiments, the battery may be omitted and replaced or augmented with a capacitor or omitted entirely. Generally, the arrangement of the elements and the circuitry of the sensor system 100, can be based on or adapted from an ABB Ability™ Smart Sensor for Mounted Bearings or an ABB Ability™ Motor Smart Sensor, for example.

The circuitry 126 is powered at least in part by the energy harvesting device 124, which in this case is a heat flux generator (e.g., a TEC or TEG), and includes or is operatively associated with one sensor or multiple sensor components 130, which can be an acceleration sensor, a temperature sensor (thermocouple or RTD), a strain sensor, a position sensor (GPS, proximity sensor, gyroscope), or an oil quality sensor (impedance sensor, particle detector and/or sizer, humidity sensor, optical sensors, resonant or conductive sensors). The sensor component 130 is configured to generate a signal indicative of a physical and/or chemical property of the machine to which the sensor system 100 is attached or associated. The physical property to be measured may be one or more of temperature, acceleration, speed, torque, and so on. The chemical property to be measured can include oil composition, metal particle presence in oil, and so on.

The sensor system 100 may be configured to send data derived from signals generated by the sensor component 130 to a processor portion of the circuitry and subsequently the raw or processed data can be transmitted via wireless transfer (e.g., via Bluetooth, Wi-Fi, NFC, Infrared) to a nearby device such as a smartphone, gateway, or another device capable of receiving the signal and collecting data. The data may then be processed off-line for the desired property output.

The heat used to generate electricity via the TEC or TEG 124 for the operation of the sensor system 100 may be generated by the internal friction or the motion of the lubricant of a machine, such as a bearing, but can be in principle any type of heat. This heat from the machine is passed through the threaded portion 108 of the base 106 and into the energy harvesting device 124, and then into a heat exchanger or heat sink 102, 104, which sheds the heat into the atmosphere.

There are many factors that determine the generated power in a thermoelectric power generation system. The power generated of a TEC is primarily dependent on the temperature and heat flow of the system (from heat source, through the sensor system 100, and to the environment). Higher temperature differentials generate more power. The low thermal conductivity of the insulator 122 prevents thermal short-circuit of the system and operates to direct heat flow to the TEC and maintain the difference in temperature between the cold and hot sides of the TEC.

The sensor system 100 may be configured to operate with 3-4 volts and a Peltier plate of the energy harvesting device 124 may only generate 20-200 mV. Therefore, the sensor system 100 thus should be configured to adapt the voltage from the energy harvesting device 124 to the desired voltage level. In this case a DC-DC converter may be employed as part of the system circuitry 126.

In the event of power shortages during certain times of the operation of the sensor system 100, especially during peak power demand times of wireless connection and sensor booting, the system is configured to generate sufficient power to charge a capacitor, which is in communication with the circuitry 126, during low energy usage periods, i.e., when the sensor system is idle, in a sleep mode, or in a deep sleep mode. The energy from the capacitor is used to carry out energy-intensive tasks such as sensor booting, data transmission, sensor wireless setup, and the capacitor is also used to provide energy during measurement and processing procedures. The capacitor can be a standard capacitor or a super capacitor. The capacitor may be placed after a DC-DC conversion step in the circuitry 126 and it may be also incorporated prior to the conversion step. The voltage being delivered to the sensor circuitry 126 should be within the specified voltage limits, typically 3-5 volts.

The power output of the Peltier plate also depends on the load resistance. To maximize the power, it is desirable to closely match the electrical resistance of the specific thermoelectric system to the sensor hardware electrical needs. For example, the TEC of the energy harvesting device 124 used may be a Peltier plate 03111-5L31-03CG made by Custom Thermoelectric LLC and power increases and reaches a maximum at 36 kΩ. Thus, the sensor component 130 should be targeted to have resistance preferably within 5% of this value. A maximum power point tracking (MPPT) system may also be used to optimize power transfer across a range of operating conditions.

Thermal resistance of the heat sink 104 should be approximately matched with the thermal resistance of the TEC of the energy harvesting device 124 to maximize the temperature differential across the TEC (for Carnot efficiency) without overly limiting heat flow through the system. However, when the temperature difference available to the system is below a threshold difference, no power may be generated.

In case where the sensor system 100 is mounted via a ⅛″-27 PTF-SAE Special Extra Short thread, the heat flow from the mechanical equipment into the TEC can be constrained due to the small diameter of the post 108. To enhance the heat flow from the mechanical device thermal grease 134 (FIG. 3) can be used in the interface of the post 108 to the machine, as well as an additional thermally conductive bridge, such as a washer 132 (FIG. 2). The washer 132 may be made of a metal or rubber, with sufficiently high thermal conductivity (>0.1 W/m-K, more preferably >1 W/m-K).

Sensor systems according to the disclosure may be powered by a variety of means which constitute alternative versions of the above disclosed system. Referring to FIG. 4, in a photovoltaic implementation of sensor system 200, solar cells or panels 140 capture sunlight or indoor light to power the sensor system. The most common photovoltaic technologies are amorphous-silicon, multi-crystalline, and monocrystalline silicon photodiodes, typically arranged in arrays in larger panels. Incoming light generates a reverse current on a semiconductor junction by way of the photoelectric effect. The power circuitry and electronics 126 are similar to the above-detailed thermoelectric implementation. A DC-DC conversion is typically required, with optional MPPT, and a capacitor to store energy for peak energy demands.

The power output from a solar cell 140 can be improved. The angle of the cell relative to the incident light will affect efficiency. An angle greater than about 60° from the normal, power will fall dramatically. Multiple cells 140 can be placed at different angles, or a light pipe can redirect incident light, to take advantage of directional light sources. Dirt contamination will also greatly reduce conversion efficiency. Hydrophobic coatings can repel some contaminates and utilize a wet environment to maintain the surface free of dirt. Consideration should be made to ensure that both packaging and any coatings on the outer surface of the sensor housing 102 are compatible with the wavelengths of peak conversion.

In the embodiment of FIG. 4, the sensors 130 are disposed outside the envelope of the housing 102 so as to be positionable directly adjacent or in contact with the device from which data is to be collected. Alternatively, the sensors 130 are outside the housing 102 and at least in operative communication with the device from which data is to be collected. In some embodiments the data collected via the sensor 130 is of greater accuracy or resolution, depending on the type of sensor and environment, relative to sensors that are positioned within the envelope of the housing 102. For example, a sensor 130 configured to detect acceleration would likely benefit significantly by not being physically spaced apart from a vibrating mechanism to be monitored. A temperature sensor 130 would also benefit the position indicated in the device of FIG. 4. Other sensor types 130 may benefit by being located within the housing. A speed sensor 130 might not be adversely affected by being located within the housing in an environment where the property being monitored generates a sufficiently detectable and resolvable signal.

Another embodiment of the disclosure contemplates an energy harvesting device comprising a vibration-based mechanism to harvest electrical energy from displacements of the surfaces to which a sensor system is mounted. Displacements at the surface of mechanical devices such as bearings are caused by vibrations in, for example, the rolling elements of the bearing. Vibrations are inherent to rolling element bearings due to periodically variable bearing compliance as the bearing rotates. The bearing compliance varies as bearing loads are distributed differently between multiple rollers over the course of a revolution. Thus, vibration-based sensor embodiments work for bearings that are within manufacturing and operating specifications and do not rely on internal bearing imperfections to generate additional surface vibrations. In gearboxes (or gear reducers) vibrations are caused by gear meshing, shaft deflections, imbalances, bearings, and housing vibration modes.

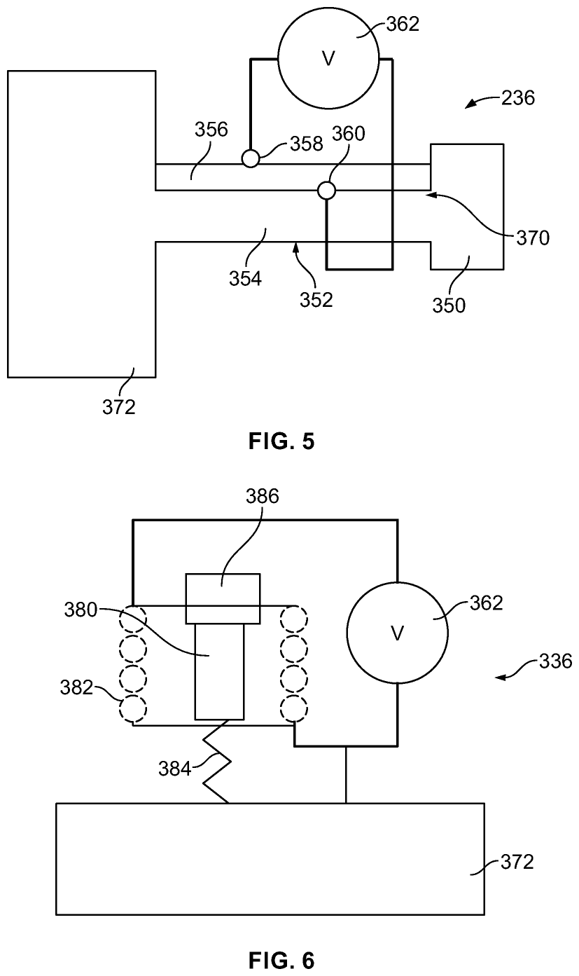

For the vibration-based system comprising the energy harvesting device 236 according to FIG. 5 to function, a seismic mass 350 and an elastic structure 352 are used to form a system with a characteristic dynamic response to a given displacement input. The energy harvesting device 236 may be positioned within a housing of a sensor system (not shown) constructed similarly to those disclosed above or adjacent and operatively associated with a sensor system as disclosed above. The resonant frequency of the vibration-based system 326 is typically chosen to match one of the prominent frequency peaks in the power spectrum of the bearing (or gearbox or electric motor) to which it is operatively associated.

One embodiment of a vibration-based system 236 for harvesting energy utilizes a cantilever beam 354 attached to a mounting surface 372 to form an elastic structure 352 that is oriented roughly perpendicular to the surface displacements when positioned in an operating position. The seismic mass 350 can be thought of as the mass of the beam itself, but an added weight at the free end 370 of the cantilever beam 354 is also an option. The resonant frequency of this system 350, 354 can be tuned to match the vibrations of the bearing or attached device by changing the location and weight of the seismic mass 350, the dimensions of the cantilever beam 354, or the material and therefore the Young's modulus of the beam.

In the embodiment of FIG. 5, a thin layer of PZT (lead zirconate titanate) or other piezoelectric material 356 is deposited on one or both surfaces of the cantilever beam 354. Electrode layers 358, 360 are formed to sandwich the PZT layers so that they can be electrically connected in parallel or in series. When the cantilever beam 354 elastically deforms by first mode bending due to its dynamic response to vibrations, piezoelectric charges are generated that lead to a voltage 362 across the electrically connected electrodes 358, 360. The voltage level is also a function of the piezoelectric constant.

FIG. 6 shows another embodiment of a vibration-based energy harvesting device 336 that utilizes a permanent magnet 380 and a pickup coil 382 to harvest vibrational energy. The energy harvesting device 336 may be positioned within a housing of a sensor system (as shown above) or adjacent and operatively associated with a sensor system as disclosed above. In this embodiment the magnet 380 is mounted on top of a spring 384 (i.e., an elastic structure) and surrounded by the pickup coil 382. An optional mass 386 or adjustments to the spring stiffness can be used to select a desired dynamic response of this system 336 to match it to vibrations of the mounting surface 372 (i.e., the excitation frequency). At the resonance of this system 336 the magnet 380 will have a maximum relative displacement with respect to the mounting surface 372 with a 90-degree phase shift assuming a second order system approximation.

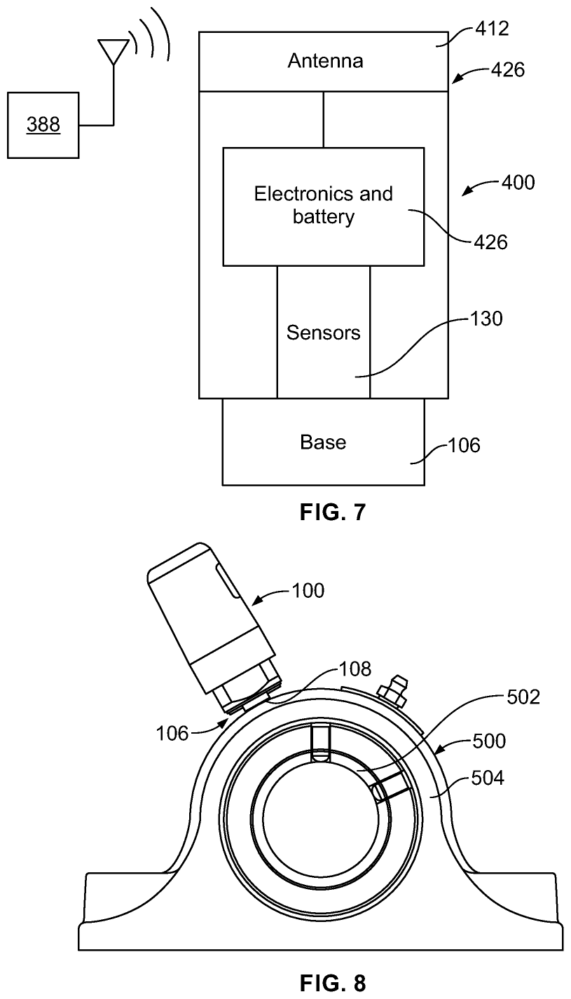

FIG. 7 shows yet another embodiment of a sensor system as detailed above with a Radio Frequency (RF) based version of an electrical energy harvesting device 436 that acquires energy from ambient RF or generated RF from a nearby RF transmitter 388. One or more RF transmitter 388 located in optimum locations transmits RF energy wirelessly to the sensor system 400 which has a receiving antenna 390 and electronic circuitry 426 or components configured to convert the RF energy to electrical voltage to recharge an onboard battery or capacitor 426 to directly power the sensor system 400. An efficient high-performance matched directional antenna 412 of the sensor system 400 is configured to harvest available RF energy. The transmitter 388 can power continuously or on an as-needed basis. The transmitter 388 can be located in a fixed location or in a mobile system which can become in close proximity to the sensor system 400 on a periodic basis. The antenna 412 in the sensor system 400 can be oriented for optimal performance. The communication frequency for the sensor system 400 and the RF harvesting frequency can be in the same range or a different range. The RF transmitter 388 can also include the gateway for communications operations. The sensor system 400 otherwise is configured to operate to acquire and transmit data from a sensor component 106 and is attached to a device to be monitored via a base 106 as detailed above.

Turning to FIG. 8, which illustrates a sensor system 100 and bearing assembly 500. The bearing assembly 500 includes a bearing set 502 retained within a bearing housing 504. Bearing housings 504 have a variety of form factors, all of which are contemplated that are typically made of steel, cast iron, polybutylene terephthalate, or other durable materials. The bearing housing 504 depicted in FIG. 8 is commonly referred to as a “pillow block.” Operation of the bearing 500 generates vibrations, for example, which can be sensed and analyzed to monitor the operational status of the bearing. In addition, the bearing assembly 500, by virtue of its attachment to adjacent structures and convey vibrations, heat, and other variables to the sensor system 100 through the housing 504, and this, too, can be a useful source of information about the operating status of the industrial equipment to which the bearing assembly is attached.

The sensor system 100 may be attached to the bearing housing 504 via the base 106. By way of the threaded connection 108 of the base 106, the sensor system 100 may be securely connected to the housing 504 providing a suitable connection for the transmission of vibrations or other information from the bearing assembly 500 to the sensor system in addition to heat transfer, for example, in some variations of the device. Other attachment methods are contemplated that are capable of providing a connection that transmits information to the sensor with a sufficient degree of resolution to make possible accurate assessment of the function of the attached device.

FIG. 9 shows a sensor system 100 and a mechanical device 600, which may be a gearbox or motor, for example, where it is desirable to monitor the operational status of the device. The sensor system 100 is attachable to the device 600 via the base portion 106 including a threaded shaft 108 extending from the sensor which is sized and shaped to be securely receivable in an internally threaded opening 610 formed in a housing or like structure 612 of the device 600.

In use, the sensor system 100 of any of the above disclosed embodiments and alternatives thereof may be paired with a suitable receiver and installed into position. Booting and initialization proceeds as in known battery-operated sensor systems. During operation of the device to which the sensor system 100 is attached, energy is harvested and stored and/or used to operate the sensor. During operation the sensor system 100 transmits data and/or other signals wirelessly to the receiver to provide an indication of the operation of the device to which it is attached as is known.

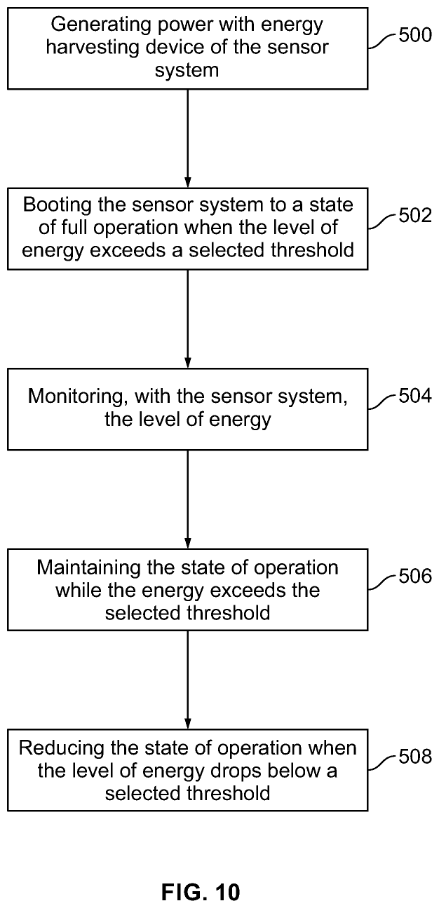

One method of operating a sensor system 100 as disclosed herein is set out in FIG. 10. The method includes generating power with an integral energy harvesting device 500. The sensor system is booted to a state of full operation when the level of energy exceeds a selected threshold 502. The sensor system monitors the level of energy available for operation 504. The full state of operation is maintained while the level of energy exceeds that required for full operation of the system 506 and the state of operation reduces when the level of energy drops below the required level 508.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and “at least one” and similar referents in the context of describing the invention (especially in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. The terms “comprising,” “having,” “including,” and “containing” are to be construed as open-ended terms (i.e., meaning “including, but not limited to,”) unless otherwise noted.

Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

We claim:

1. A sensor system for monitoring a device, the sensor system comprising:
a housing;
a base configured to attach the sensor system to the device to be monitored;
a sensor configured to obtain data related to at least one operating parameter of the device; and
an integral energy harvesting device configured to provide at least a portion of the energy required to operate the sensor system.

2. The sensor system of claim 1 wherein the sensor is configured to measure one or more of temperature, acceleration, oil quality, torque, and rotational speed.

3. The sensor system of claim 1 wherein the energy harvesting device is configured to harvest one or more of thermal, photovoltaic, acceleration, and RF.

4. The sensor system of claim 1 further comprising one or more of a battery and a capacitor.

5. The sensor system of claim 1 further comprising a super capacitor.

6. The sensor system of claim 1 further comprising a DC-DC converter in communication with the energy harvesting device, the DC-DC converter configured to boost power from the energy harvesting device.

7. The sensor system of claim 1 wherein the housing is configured as a heat sink.

8. The sensor system of claim 7 wherein the housing includes cooling fins.

9. The sensor system of claim 7 wherein a thermal insulator is disposed between the base and the housing.

10. The sensor system of claim 9 wherein the base is made of a base material having a first thermal conductivity and the housing is made of a housing material having a second thermal conductivity, the first thermal conductivity greater than the second thermal conductivity.

11. The sensor system of claim 1 wherein the energy harvesting device is disposed between the base and the housing.

12. The sensor system of claim 1 wherein the energy harvesting device is contained within the housing.

13. The sensor system of claim 1 wherein the sensor is exterior to the housing.

14. The sensor system of claim 1 wherein the sensor is contained within the housing.

15. The sensor of claim 1 wherein the base includes a threaded post.

16. A bearing assembly and sensor system, comprising:
a bearing assembly comprising:
a bearing housing and
a bearing set disposed in the bearing housing;
a sensor system attached to the bearing housing, the sensor system comprising:
a housing;
a base configured to attach the sensor system to the device to be monitored;
a sensor configured to obtain data related to at least one operating parameter of the device; and
an integral energy harvesting device configured to provide at least a portion of the energy required to operate the sensor system.

17. A method of operating a wireless sensor system, comprising:
generating power with an integral energy harvesting device;
booting the sensor system to a state of full operation when the level of energy exceeds a selected threshold;
monitoring, with the sensor system, the level of energy;
maintaining the full state of operation while the level of energy exceeds that required for full operation of the system; and
reducing the state of operation when the level of energy drops below the required level.

18. The method of claim 17 wherein generated power is stored in one or both of a battery and a capacitor of the sensor system.

19. The method of claim 17 wherein the energy harvesting device is configured to generate power using one or more of thermal, solar, RF, and vibration energy.

20. The method of claim 17 wherein the wireless sensor system is configured to monitor the status of a bearing assembly.
